(19) United States
(12) Patent Application Publication
(10) Pub. No.: US 2015/0364399 A1
(43) Pub. Date: Dec. 17, 2015

(54) CHIP PACKAGE ASSEMBLY AND METHOD TO USE THE ASSEMBLY

(71) Applicant: Siemens Research Center Limited Liability Company, Moscow (RU)

(72) Inventors: Evgeny IVANOV, Moscow (RU); Andrey KRASNOV, Moscow (RU); Georgy SHARKOV, Moscow (RU); Nadezhda TIKHOMIROVA, Rybinsk (RU)

(73) Assignee: Siemens Research Center Limited Liability Company, Moscow (RU)

(21) Appl. No.: 14/760,753

(22) PCT Filed: Jan. 16, 2013
(86) PCT No.: PCT/RU2013/000031

§ 371 Date: Jul. 14, 2015

(51) Int. Cl. H01L 23/367; H05K 3/34; H01L 23/31; H01L 23/498; H01L 23/373

(52) U.S. Cl. CPC H01L 23/367; H01L 23/49838; H01L 23/3736; H01L 23/3121; H01L 23/49811; H05K 3/34

(57) ABSTRACT

A chip package assembly and its use for mounting and demounting of at least one semiconductor chip that includes a flange and a substrate, where the at least one chip and the substrate are arranged on one side of the flange, and where the flange is composed of an electrical and thermally conducting material.

### CROSS-REFERENCE TO RELATED APPLICATIONS

This is a U.S. national stage of application No. PCT/RU2013/000031 filed 16 Jan. 2013.

### BACKGROUND OF THE INVENTION

1. Field of the Invention

The present invention relates to chip packages and, more particularly, to a chip package assembly and its use for mounting at least one semiconductor chip, comprising a flange and a substrate, where the at least one semiconductor chip and the substrate are arranged on one side of the flange.

The present invention describes a chip package assembly which can be used for mounting and encapsulation of semiconductor chips containing for example vertical junction field effect transistors (VJFET).

2. Description of the Related Art

Inter alia high power RF semiconductor devices can be composed of VJFET structures. Chip packages are known, for example, from U.S. Pat. No. 6,318,622B1, U.S. Pat. No. 6,967,400B2, U.S. Pat. No. 6,465,883B2 and U.S. Pat. No. 7,256,494B2.

In U.S. Pat. No. 6,318,622B1 describes an assembly of high power chips that mounts to an additional substrate. Semiconductor chips are electrically connected to the main substrate by bonding wires. Ribbon connectors are used for external electrical connection. To protect the internal structure of the assembly an extra cap is used.

U.S. Pat. No. 6,967,400B2 describes an IC chip package including a substrate, a chip, adhesive means, a cover and a spacer. Vias at the end faces of the substrate are used for external electrical connection, where bonding wires pass through the vias. This provides a good possibility to connect the semiconductor chip electrically from outside the package.

Two main problems arise from the described conventional assemblies, i.e., the problem of connecting several substrates together and the problem of heat transfer. In practice, high power devices produce huge amounts of heat during use. This heat must be transferred to the environment, must not to exceed a critical temperature of the device and in worst case must not destroy the devices by a temperature exceeding the critical temperature. There is no possibility given to improve heat transfer, for example, by use of external cooling blocks.

U.S. Pat. No. 6,465,883B2 describes a high power transistor chip for high frequencies that is coupled to an electrically and thermally conductive flange at its backside.

U.S. Pat. No. 7,256,494B2 describes a chip package including a heat spreader at the backside of a chip. Here, electrical connectors are provided for the gate and drain of a transistor to be electrically connected with the substrate mount on top of the flange or heat spreader. The described conventional assemblies exhibit good thermal properties, but are restricted to use for applications where the electrical insulation of the flange or heat spreader from the ground is required. This electrical insulation is required, for example, with the use of VJFET chips with the drain connector located at the bottom of the chip.

### SUMMARY OF THE INVENTION

It is therefore an object of the present invention to provide a chip package assembly with high efficiency of heat removal from a semiconductor chip, particularly for semiconductor chips with a transistor drain contact connection on the bottom side of the semiconductor chip. The bottom side of the semiconductor chip is the side opposite to the side with other electrical contacts such as source contacts and electrical connections of the semiconductor chip to external devices. The bottom side is the side with which the semiconductor chip is arranged on a mounting structure. A further object of the present invention is to provide a chip package assembly and method of use with the ability to mount and demount the semiconductor chip from the assembly. If the semiconductor chip shows a failure, it is advantageous to be able to easily remove and/or exchange the semiconductor chip with a properly functioning chip.

The foregoing objects and advantages are achieved in accordance with the invention by providing a chip package assembly and method for its use, where the chip package assembly for mounting at least one semiconductor chip in accordance with the present invention comprises a flange and a substrate, where the at least one semiconductor chip and the substrate are arranged on one side of the flange. In this case, the flange is the previously described mounting structure. The flange is composed of an electrical and thermally conducting material. This means that the material has a low electrical and thermal resistance compared to other materials like isolators.

The advantage of the chip package assembly in accordance with the present invention is a high efficiency of heat removal from the at least one semiconductor chip due to the flange. The semiconductor chip can have a transistor drain contact connection on the bottom side of the chip and still the flange can be thermally coupled to this side. The assembly is easy to use and easy to assemble, with a low number of parts, is cost effective and can be used in high frequency applications.

The conducting material of the flange can comprise or can be made of a metal, particularly a metal with high thermal conductivity, particularly copper. A flange made of copper shows a high thermal conductivity and is able to transfer heat away from the semiconductor chip well, which is produced, for example, in high power applications of the semiconductor chip. Cooling and keeping the semiconductor chip below a critical temperature in use also prevents damage and failure of the semiconductor chip.

The substrate can comprise a material with low losses at high frequencies. The substrate can, for example, be made of printed circuit board (PCB) material. This material does not adsorb much signal in high frequency applications; radiation with high frequency can pass it with little or no loss. PCB material is cheap, can be easy handled, is mechanically stable and other electronic or electric components such as electrical contacts can easy be arranged on such boards.

The at least one chip can comprise a transistor drain contact connection at the bottom side. The bottom side is the side facing the flange and is particularly opposite to the side with the other electrical contacts of the at least one semiconductor chip. The chip package assembly in accordance with the present invention allows also for a semiconductor chip with a transistor drain contact connection at the bottom side to fix it at the same side to a flange, respectively a cooling device.

The at least one semiconductor chip and/or substrate can be mounted on the one side of the flange using solder, eutectic alloy, electrical conductive adhesive and/or sinter paste. This allows easy and cost effective arrangement of the at least one semiconductor chip and/or substrate to the flange.

Connectors of the at least one semiconductor chip, particularly the connectors on the side of the at least one semiconductor chip opposite the side facing the flange, can be connected to the substrate by bonding, particularly by bonding with wires and/or ribbon lines. This gives an easy and good electrical connection between the at least one semiconductor chip and the substrate.

The chip package assembly can comprise electrical outlets for high frequency requirements connectable to external devices, particularly to an amplifier Printed Circuit Board. This makes it easy to use the chip package assembly in high frequency applications.

The substrate can comprise end side metalized places for electrical contact, particularly in electrical contact to the at least one semiconductor chip, for electrical contact to at least one external device. The end side metalized places can be arranged at the side face of substrate and/or soldered for contact to the at least one external device. The arrangement of the end side of metalized parts of substrate for electrical contact at side faces and soldering makes it easy to electrically contact external devices to the contacts. This arrangement makes it easy to contact electrically the semiconductor chip with external devices. The end side metalized places are easy to reach for electrical connection.

The chip package assembly can comprise an electrical isolation between the connectors of the at least one semiconductor chip and the flange. This prevents short circuits over the flange of the semiconductor chip contacts, especially for good electrically conducting flanges like the one made of copper.

The chip package assembly can comprise at least one cooling device, particularly a cooling block. Also other active or passive cooling devices can be thermally connected to the flange of the chip package assembly. For example, devices with a water cooling circuit or with an air fan can be used. This enables a good cooling of the at least one semiconductor chip even in high power applications with high amounts of waste heat. The chip package assembly can also comprise means for mounting the flange with the at least one semiconductor chip and the substrate to the cooling device. This means can be, for example, screws.

An electrical isolation can be arranged between the connectors of the at least one semiconductor chip and the cooling device. This prevents short circuits between connectors and/or via the cooling device. This prevents short circuits between connectors and/or via the cooling device.

The chip package assembly can comprise a dielectric substrate between the flange and the cooling device, particularly in plate form. It can be arranged on the opposite side of the flange, to the one side of the flange where the at least one semiconductor chip and the substrate are arranged, for electrical isolation.

The chip package assembly can further comprise an encapsulation to protect the at least one semiconductor chip and connectors. The encapsulation can be removable. This enables an easy exchange of semiconductor chips from the assembly such as if the semiconductor chip in use has a fail function.

The chip package assembly can comprise screws through dielectric sleeves to fasten the at least one semiconductor chip, substrate and flange to the cooling device. This enables an easy, fast and reliable assembly of the chip package assembly without electrical short circuits due to the screws.

A method to use the chip package assembly in accordance with the present invention comprises demounting of the chip package, particularly to demount the at least one chip from the substrate. This is also enabled by the arrangement of parts as described before for the chip package assembly itself. It allows the exchange of the at least one chip, especially if it shows a failure, with another, properly working chip.

The advantages in connection with the described method to use the chip package assembly in accordance with the present invention are similar to the previously, in connection with the chip package assembly described advantages.

Other objects and features of the present invention will become apparent from the following detailed description considered in conjunction with the accompanying drawings. It is to be understood, however, that the drawings are designed solely for purposes of illustration and not as a definition of the limits of the invention, for which reference should be made to the appended claims. It should be further understood that the drawings are not necessarily drawn to scale and that, unless otherwise indicated, they are merely intended to conceptually illustrate the structures and procedures described herein.

### BRIEF DESCRIPTION OF THE DRAWINGS

The present invention is further described hereinafter with reference to illustrated embodiments shown in the accompanying drawings, in which:

FIG. 1 illustrates an embodiment of a chip package assembly 1 for mounting at least one semiconductor chip 2 in accordance with the present invention; and

FIG. 2 illustrates the chip package assembly 1 of FIG. 1 with means for mounting it to a cooling device (not shown).

### DETAILED DESCRIPTION OF THE EXEMPLARY EMBODIMENTS

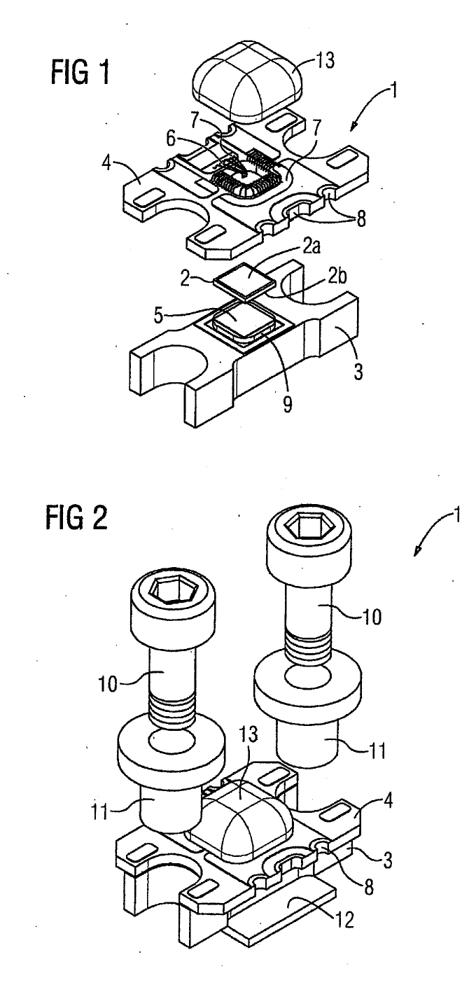

Shown in FIG. 1 is an embodiment of the chip package assembly 1 in accordance with the present invention, for mounting at least one semiconductor chip 2. The chip package assembly 1 comprises a semiconductor chip 2, particularly with transistor connections, for example, for the gate and source on the top side of the chip 2a and with drain connection on the bottom side of the chip 2b. The chip package assembly 1 further comprises a flange 3, on which the semiconductor chip 2 and a substrate 4 are arranged on one side. The flange 3 operates as a cooling device, which has a good thermal conductivity.

During usage, the semiconductor chip 2 produces waste heat. In high power applications the waste heat can increase the temperature of the semiconductor chip 2 and damage it. This is why heat must be removed and transferred to the environment, to cool down the semiconductor chip 2 and/or to keep the temperature of the semiconductor chip 2 below a critical temperature. Above the critical temperature the electronic device of the semiconductor chip 2 can show failure and/or can be damaged. The flange 3, which is in good thermal contact to the chip 2, absorbs the waste heat of the semiconductor chip 2 and transfers it directly to the environment or to an additional cooling device, which is not shown in the figures for simplicity. An appropriate material for the flange 3 to consist of or to comprise is a metal with high thermal conductivity, such as copper.

For good mechanical and thermal connection between the semiconductor chip 2 and the flange 3, materials 5 for attachment of the semiconductor chip 2 are solders, eutectic alloys, electrical conductive adhesives and/or sinter paste. The semiconductor chip 2 and/or substrate 4 can be mounted on one and the same side of the flange using these materials. In between the semiconductor chip 2 and the flange 3 an electrical isolation 9 can be arranged. The electrical isolation can be made of a plate like isolating material, which prevents short circuits between the electrical connectors of the at least one semiconductor chip 2 and electrical contacts between the semiconductor chip 2 and the flange 3.

The substrate 4 is arranged on the same side of the flange 3 as the semiconductor chip 2, and it can comprise a recess within, where the semiconductor chip 2 can be arranged. Electrical outlets 7 on the substrate 4 are used to electrically contact the semiconductor chip 2. One way of electrically connect the semiconductor chip 2 and substrate 4 is bonding, for example, bonding with wires and/or ribbon lines 6. The electrical outlets 7 can extend to end-side metalized places of substrate 8. They can be arranged at side faces of the substrate 4 and can be soldered. The end-side metalized places of substrate 8 are suitable for electrical connection with external devices, for example, by wires soldered to the places 8. Via the end side metalized places and the electrical outlets 7 of substrate 8, bonded, for example, with wires and/or ribbon lines 6 to contact connections of the semiconductor chip 2, semiconductor the chip 2 can be electrically connected with external devices (not shown in figures for simplicity).

On top of the semiconductor chip 2, with its contact connections and bonded wires and/or ribbon lines 6, an encapsulation 13 can be arranged to protect the semiconductor chip 2 and connections mechanically and electrically. The encapsulation 13 or cover can be made of a polymer, which is not electrically conducting. It can be arranged and connected removable from the assembly to be able to exchange the semiconductor chip 2 if necessary.

As shown in FIG. 2, the chip package assembly 1 can comprise means 10, 11 for mounting it to an additional cooling device, (not shown for simplicity). The cooling device can, for example, be a plate with a fin structure or a water cooled heat exchanger. Possible devices for mounting are screws 10, which can be screwed into the cooling device, and with their screw heads the substrate 4 and flange 3 can be compressed or clamped together and to the additional cooling device. A dielectric substrate 11 can be arranged between the flange 3 and the cooling device to electrically isolate the flange 3 from the cooling device. The isolation can be necessary in high frequency applications, if a current is induced in the flange 3. The isolation reduces induction losses by induced currents. The substrate 4, flange 3, isolator 12 and cooling device can be arranged in a sandwich structure, which is compressed and fixed to each other by the clamps 10.

Dielectric sleeves 11 can be used to electrically isolate the screws 10 from the flange 3. The sleeves 11 can have a cupped form with washer head. The chip package assembly 1 can be clamped together in a sandwich like form by the means 11 and 12, and can be mechanically stably fixed or mounted to the cooling device.

Isolation of electrical conductive parts, such as flange 3, external cooling device and screws, from each other can improve the performance of the assembly 1, and makes its use possible in high frequency applications.

Features of the above described embodiments of the invention with itself and features from embodiments known from the state of the art can be combined. Different materials and forms of parts of the described assembly 1 are possible. For example, the flange 3 can be made, instead of copper, out of steel or other materials, particularly metals. The H like shape of the substrate 4 and the flange 3, with recesses for means 10, 11 to fix the assembly 1 together can, for example, also have a shape of an 8. Instead of an external cooling device, nuts can be used in connection with screws 10 to clamp the assembly 1 together.

A method to use the chip package assembly 1 comprises mounting the semiconductor chip 2 on the flange 3, for example, by using solder, eutectic alloy, electrical conductive adhesive and/or sinter paste 5. In between an electrical isolation 9 can be arranged. Around the semiconductor chip 2, on the same side of the flange 3 a substrate 4 is arranged, such as by also using solder, eutectic alloy, electrical conductive adhesive and/or sinter paste 5. The semiconductor chip 2 and electrical outlets 7 of the substrate 4 are electrically connected together, for example, by bonding with bond wires or ribbon lines 6. The electrical outlets 7 can extend to side faces of the substrate 4, which can be soldered for good electrical contact to external electrical devices like amplifiers. Arranging the semiconductor chip 2 on the flange 3 and not direct on the substrate 4, can permit a better heat transfer between the semiconductor chip 2 and flange 3.

An encapsulation 13 can be arranged on top of the semiconductor chip 2 and on top of electrical connections 6 to the outlets 7 of substrate 4. The encapsulation 13 can be in the form of a cap, which is removable. Alternatively, the semiconductor chip 2 can be enclosed in a casting compound. This can be a usual polymer used in the semiconductor industry to encapsulate semiconductor chips.

The use of removable encapsulation 13, which can be clamped by the means 10, 11 or glued to the substrate 4, enables an easy exchange of the semiconductor chip 2. The chip package assembly 1 can be demounted, particularly the at least one semiconductor chip (2) can be demounted from the substrate 4. For example, if the mounted semiconductor chip 2 shows a failed function in use, the semiconductor chip 2 can be exchanged with another, properly working chip. After removal of the encapsulation 13 bonding material 6 is removed, the semiconductor chip 2 is peeled of the flange 3, a new chip 2 is arranged on the flange 3 and, for example, is fixed using solder, eutectic alloy, electrical conductive adhesive and/or sinter paste 5. The semiconductor chip 2 connections and electrical outlets 7 on the substrate 4 are bonded together electrically. And the encapsulation is affixed to the assembly 1, for example, on top of the semiconductor chip 2, as shown in FIGS. 1 and 2.

Other additional steps are possible. For example a cleaning step of parts can be used to remove glue or solder, eutectic alloy, electrical conductive adhesive and/or sinter paste. The steps of the method according to the present invention can also be performed in another timely order. Also steps known from the state of the art can be performed alternatively or additionally to the described steps of the method according to the present invention.

Thus, while there have shown, described and pointed out fundamental novel features of the invention as applied to a preferred embodiment thereof, it will be understood that various omissions and substitutions and changes in the form and details of the devices illustrated, and in their operation, may be made by those skilled in the art without departing from the spirit of the invention. For example, it is expressly intended that all combinations of those elements which perform substantially the same function in substantially the same way to achieve the same results are within the scope of the invention. Moreover, it should be recognized that structures and/or elements shown and/or described in connection with any disclosed form or embodiment of the invention may be incorporated in any other disclosed or described or suggested form or embodiment as a general matter of design choice. It is the intention, therefore, to be limited only as indicated by the scope of the claims appended hereto.

1.-15. (canceled)

16. A chip package assembly for mounting at least one semiconductor chip, comprising:
a flange; and
a substrate, the at least one semiconductor chip and the substrate being arranged on one side of the flange;
wherein the flange is composed of an electrical and thermally conducting material.

17. The chip package assembly according to claim 16, wherein the conducting material of the flange comprises a metal.

18. The chip package assembly according to claim 16, wherein the substrate comprises a material with low losses at high frequency.

19. The chip package assembly according to claim 17, wherein the substrate comprises a material with low losses at high frequency.

20. The chip package assembly according to claim 16, wherein the at least one semiconductor chip comprises a transistor drain contact connection at a bottom side which faces the flange and is particularly opposite to a side with other electrical contacts of the at least one chip.

21. The chip package assembly according to claim 16, wherein at least one of the at least one semiconductor chip and substrate are mounted on the one side of the flange using at least one of solder, eutectic alloy, electrical conductive adhesive and sinter paste.

22. The chip package assembly according to claim 16, wherein connectors of the at least one semiconductor chip comprising connectors on the side of the at least one chip opposite the side facing the flange, are connected to the substrate by bonding comprising bonding with at least wires and ribbon lines.

23. The chip package assembly according to claim 16, further comprising:
electrical outlets for high frequency requirements connectable to external devices comprising an amplifier printed circuit board.

24. The chip package assembly according to claim 16, wherein the substrate comprises end side metalized places for electrical contact, particularly in electrical contact to the at least one chip, for electrical contact to at least one external device.

25. The chip package assembly according to claim 8, wherein the end side 24 metalized places are arranged at the side face of the substrate and or soldered for contact to the at least one external device.

26. The chip package assembly according to claim 16, further comprising:
an electrical isolation between the connectors of the at least one semiconductor chip and the flange.

27. The chip package assembly according to one of the claim 16, further comprising:
at least one cooling device comprising at least one of (i) a cooling block and (ii) means for mounting the flange with the at least one chip and the substrate to the cooling device.

28. The chip package assembly according to claim 27, further comprising:
an electrical isolation between the connectors of the at least one chip and the cooling device.

29. The chip package assembly according to claim 16, further comprising:
a dielectric substrate between the flange and the cooling device, the dielectric substrate being at least one of (i) in plate form, and (ii) arranged on the opposite side of the flange to the one side of the flange where the at least one chip and the substrate are arranged.

30. The chip package assembly according to claim 16, further comprising at least one of (i) an encapsulation to protect the at least one chip and connectors, particularly a removable encapsulation, and (ii) screws through dielectric sleeves to fasten the at least one semiconductor chip, substrate and flange to the cooling device.

31. The chip package assembly according to claim 16, wherein the conducting material is a metal with high thermal conductivity, particularly copper.

32. The chip package assembly according to claim 16, wherein the metal with high thermal conductivity is copper.

33. The chip package assembly according to claim 16, wherein the substrate is made of printed circuit board material.

34. The chip package assembly according to claim 16, wherein the encapsulation is removable.

31. A method to use the chip package assembly of the claim 16, comprising demounting the chip package so as to demount the at least one semiconductor chip from the substrate and exchange the at least one semiconductor chip with another chip.
